(19) United States
(12) Patent Application Publication
(10) Pub. No.: US 2026/0344497 A1
(43) Pub. Date: Oct. 29, 2026

(54) INTEGRATED CIRCUIT PACKAGES AND METHODS

(71) Applicant: Taiwan Semiconductor Manufacturing Co., Ltd., Hsinchu (TW)

(72) Inventors: Sheng-Han Tsai, Hsinchu (TW); Tsung-Yu Chen, Hsinchu (TW); Wensen Hung, Zhubei City (TW); Yen-Pu Chen, Hsinchu (TW)

(21) Appl. No.: 19/732,466

(22) Filed: Jul. 6, 2026

Related U.S. Application Data
(63) Continuation of application No. 18/672,879, filed on May 23, 2024.

(51) Int. Cl. H10W 72/90; H10W 99/00; H10W 72/00; H10W 76/153; H10W 80/00; H10W 90/00

(52) U.S. Cl. CPC H10W 72/90; H10W 99/00; H10W 72/0198; H10W 72/926; H10W 72/9445; H10W 72/952; H10W 72/963; H10W 72/967; H10W 76/153; H10W 80/312; H10W 80/327; H10W 90/00; H10W 90/792

(57) ABSTRACT

An integrated circuit package and the method of forming the same are provided. The integrated circuit package may include a first die, which may include a first semiconductor substrate, a first interconnect structure on the first semiconductor substrate, and a first seal ring. The first interconnect structure may include a first plurality of dielectric layers, a first plurality of metallization patterns in the first plurality of dielectric layers. The first seal ring may be in the first plurality of dielectric layers and may encircle the first plurality of metallization patterns in a top-down view. The integrated circuit package may further include a first bonding layer on the first interconnect structure, a first die connector and a second die connector in the first bonding layer. The first seal ring may encircle the first die connector and the second die connector may be outside the first seal ring in the top-down view.

### CROSS-REFERENCE TO RELATED APPLICATIONS

This application is a continuation of U.S. Patent Application No. 18/672,879, filed on May 23, 2024, and entitled “Integrated Circuit Packages and Methods,” which application is incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D illustrate cross-sectional views and bottom-up views of an integrated circuit die, in accordance with some embodiments.

FIGS. 2A, 2B, 2C, 2D, 3A, 3B, 3C, 4, 5, 6, 7, 8, 9, 10A, 10B, and 10C illustrate cross-sectional views and top-down views of intermediate processing steps in the formation of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit package and a method of forming the same are provided. In accordance with some embodiments, the integrated circuit package may comprise one or more upper integrated circuit dies bonded to a lower integrated circuit die. The upper integrated circuit dies may comprise interconnect structures with seal rings in the interconnect structures, bonding layers on the interconnect structures, and dummy die connectors in the bonding layers. The dummy die connectors may be disposed outside a stiffener ring in a bottom-up view. The lower integrated circuit die may comprise an interconnect structure with a seal ring in the interconnect structure, a bonding layer on the interconnect structure, and dummy die connectors in the bonding layer. The dummy die connectors may be disposed outside the seal ring in a top-down view. By bonding the dummy die connectors of the upper integrated circuit dies and the dummy die connectors of the lower integrated circuit die, the bonding strength between the upper integrated circuit dies and the lower integrated circuit die may be enhanced, which may eliminate or reduce the risk of delamination of the upper integrated circuit dies during the manufacturing and the operation of the integrated circuit package. As a result, the heat generated in the lower integrated circuit die may be more effectively dissipated, thereby improving the performance and reliability of the integrated circuit package.

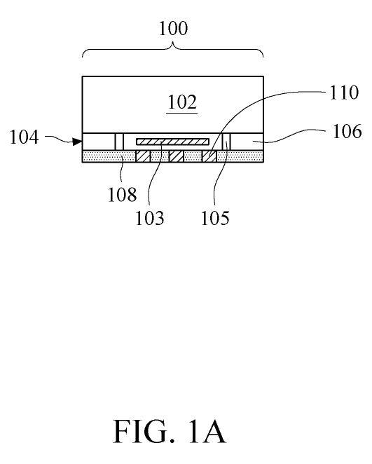

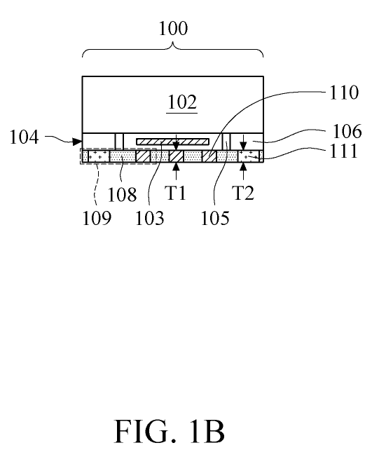

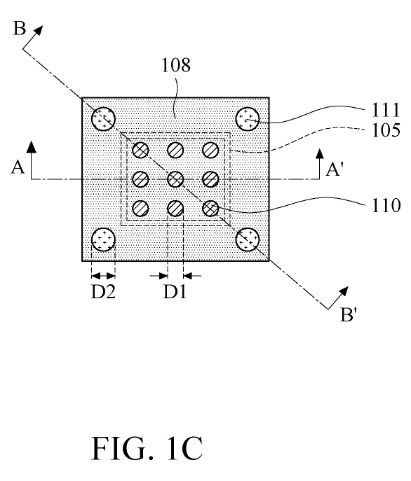

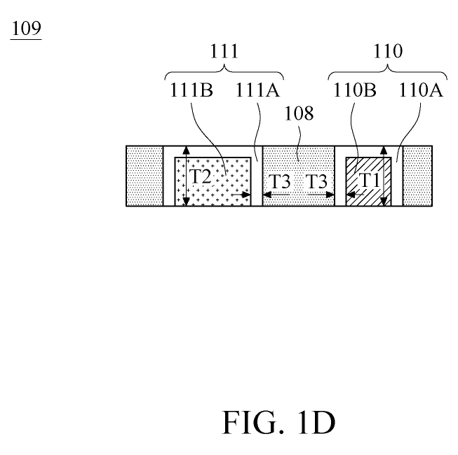

In FIGS. 1A, 1B, and 1C, an upper integrated circuit die 100 is shown. The cross-sectional view shown in FIG. 1A may be obtained along reference cross-section A-A’ in the bottom-up view shown in FIG. 1C and cross-sectional view shown in FIG. 1B may be obtained along reference cross-section B-B’ in the bottom-up view shown in FIG. 1C. The upper integrated circuit die 100 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The upper integrated circuit die 100 may have a semiconductor substrate 102, such as doped silicon, undoped silicon, an active layer of a semiconductor-on-insulator (SOI) substrate, or the like. The semiconductor substrate 102 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The semiconductor substrate 102 may have an active surface (e.g., the surface facing downwards in FIG. 1A), which may be called a front side, and an inactive surface (e.g., the surface facing upwards in FIG. 1A), which may be called a back side. The back side of the semiconductor substrate 102 may also be referred to as a back side of the upper integrated circuit die 100 and the front side of the semiconductor substrate 102 may face a front side of the upper integrated circuit die 100.

Devices (not separately illustrated) may be disposed at the active surface of the semiconductor substrate 102. The devices may be active devices (e.g., transistors, diodes, etc.), capacitors, resistors, or the like. The devices may generate a large amount of heat during operation. An interconnect structure 104 may be disposed on the active surface of the semiconductor substrate 102. The interconnect structure 104 may interconnect the devices to form an integrated circuit of the upper integrated circuit die 100. The interconnect structure 104 may comprise metallization patterns 103 in dielectric layers 106. The dielectric layers 106 may be low-k dielectric layers comprising suitable dielectric materials, such as silicon dioxide, silicon nitride, silicon oxynitride, or the like. The dielectric layers 106 may be formed by a suitable deposition process, such as chemical vapor deposition (CVD), atomic layer deposition (ALD), or the like. The metallization patterns 103 may include metal lines and vias, which may be formed in the dielectric layers 106 by a damascene process, such as a single damascene process, a dual damascene process, or the like. The metallization patterns 103 may be formed of a suitable conductive material, such as copper, tungsten, aluminum, silver, gold, a combination thereof, or the like. The metallization patterns 103 may be electrically coupled to the devices.

The interconnect structure 104 may further comprise a seal ring 105 in the dielectric layers 106. The seal ring 105 is shown in dash lines in FIG. 1C for illustrative purposes. In some embodiments, the seal ring 105 extends through the dielectric layers 106. The seal ring 105 may encircle the metallization patterns 103 in a bottom-up view and a region between the seal ring 105 and sidewalls of the interconnect structure 104 may be referred to as a keep-out zone (KOZ) of the interconnect structure 104. The KOZ may be free of the metallization patterns 103. The seal ring 105 may be formed of the same or similar material and by the same or similar process as the metallization patterns 103. The seal ring 105 may be electrically isolated from the integrated circuit of the upper integrated circuit die 100.

A bonding layer 108 may be disposed on the interconnect structure 104 at the front side of each upper integrated circuit die 100. The bonding layer 108 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; or the like. The bonding layer 108 may be formed by CVD, ALD, or the like. One or more passivation layer(s) (not separately illustrated) may be disposed between the bonding layer 108 and the interconnect structure 104.

Active die connectors 110 and dummy die connectors 111 may be disposed in the bonding layer 108. The active die connectors 110 and dummy die connectors 111 may be also referred to as bonding pads and may be used for bonding with another integrated circuit die in a subsequent process. The active die connectors 110 may be electrically coupled with the metallization patterns 103 and the integrated circuit of the upper integrated circuit die 100. The dummy die connectors 111 may be electrically isolated from the integrated circuit of the upper integrated circuit dies 100. As shown in FIG. 1C, the active die connectors 110 may be encircled by the seal ring 105 in the bottom-up view, and the dummy die connectors 111 may be outside the seal ring 105 and adjacent corners of the upper integrated circuit die 100 in the bottom-up view. The dummy die connectors 111 may be directly over and adjacent the KOZ of interconnect structure 104. The dummy die connectors 111 may enhance the bonding strength between the upper integrated circuit die 100 and another integrated circuit die in a region adjacent the KOZ of the upper integrated circuit die 100, as described in great details below.

The active die connectors 110 and the dummy die connectors 111 may have shapes of circles, polygons (e.g., rectangles), or the like in the bottom-up view. The dummy die connectors 111 may have larger sizes than the active die connectors 110 in the bottom-up view. In the embodiments shown in FIGS. 1A, 1B, and 1C, the active die connectors 110 and the dummy die connectors 111 have shapes of circles. The active die connectors 110 may have a diameter D1 in a range from about 5 µm to about 10 µm. The dummy die connectors 111 may have a diameter D2 in a range from about 20 µm to about 60 µm, which may lead to sufficient bonding strength between the upper integrated circuit die 100 and another integrated circuit die in a region adjacent the KOZ of the upper integrated circuit die 100, as described in great details below. In some embodiments, the diameter D2 is larger than the diameter D1. The active die connectors 110 and the dummy die connectors 111 may partially or completely extend through the bonding layer 108. In the embodiments shown in FIGS. 1A, 1B, and 1C, the active die connectors 110 and the dummy die connectors 111 completely extend through the bonding layer 108. The active die connectors 110 may have a thickness T1 in a range from about 0.2 µm to about 1 µm. The dummy die connectors 111 may have a thickness T2 in a range from about 0.2 µm to about 1 µm. In some embodiments, the thickness T1 equals to the thickness T2.

The active die connectors 110 and the dummy die connectors 111 may be formed by one or more damascene processes, such as single damascene processes, dual damascene processes, or the like. In some embodiments, the active die connectors 110 and the dummy die connectors 111 are formed of a same material, such as copper. In such embodiments, the active die connectors 110 and the dummy die connectors 111 may be formed by a same process. In some embodiments, the active die connectors 110 and the dummy die connectors 111 are formed of different materials. For example, the active die connectors 110 may be formed of copper and the dummy die connectors 111 may be formed of aluminum, solder, or the like. In such embodiments, the active die connectors 110 and the dummy die connectors 111 may be formed by different processes.

FIG. 1D shows a region 109 of the structure shown in FIG. 1B, in accordance with some embodiments. The active die connectors 110 may comprise a barrier sublayer 110A and a conductive sublayer 110B, and the dummy die connectors 111 may comprise a barrier sublayer 111A and a conductive sublayer 111B. The conductive sublayer 110B and the conductive sublayer 111B may comprise the same materials as described above with respect to the active die connectors 110 and the dummy die connectors 111, respectively. The barrier sublayer 110A and the barrier sublayer 111A may prevent the materials of the conductive sublayer 110B and the conductive sublayer 111B from diffusing into the interconnect structure 104. The barrier sublayer 110A and the barrier sublayer 111A may comprise tantalum, tantalum nitride, titanium, titanium nitride, or the like, and may be formed before the conductive sublayer 110B and the conductive sublayer 111B by physical vapor deposition (PVD), plating, or the like. The barrier sublayer 110A and the barrier sublayer 111A may have a thickness T3 in a range from about 0.05 µm to about 0.3 µm.

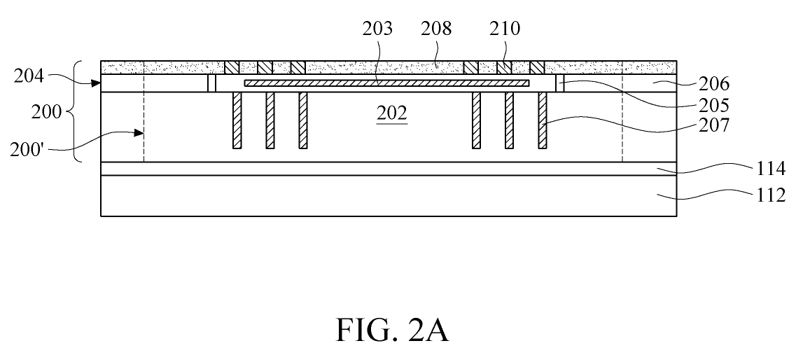

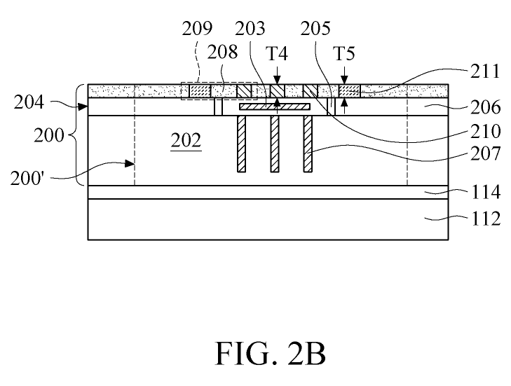

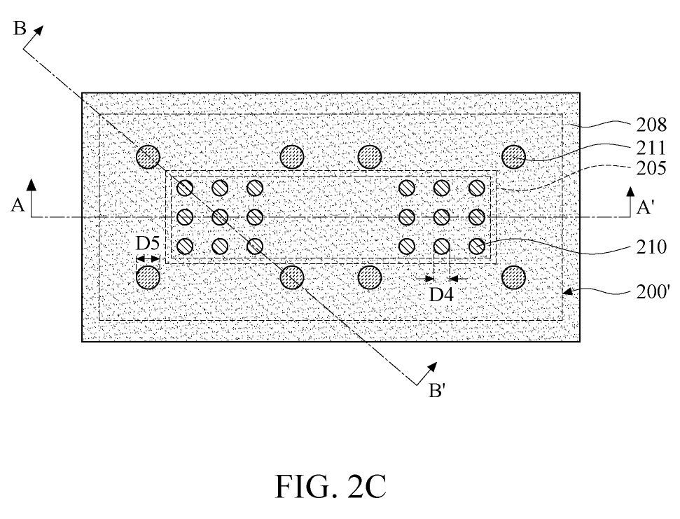

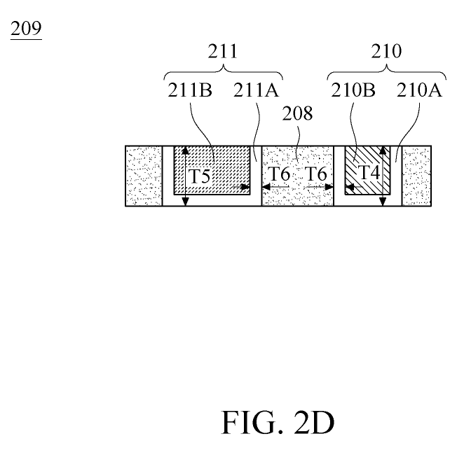

FIGS. 2A-10C illustrate intermediate processing steps in forming an integrated circuit package, in accordance with some embodiments. In FIGS. 2A, 2B, and 2C, a wafer structure 200 is attached to a carrier 112 by an adhesive 114. The cross-sectional view shown in FIG. 2A may be obtained along reference cross-section A-A’ in the top-down view shown in FIG. 2C and cross-sectional view shown in FIG. 2B may be obtained along reference cross-section B-B’ in the top-down view shown in FIG. 2C. The wafer structure 200 may be subsequently singulated into to one or more lower integrated circuit dies 200’. Sidewalls (e.g., borders) of the projected lower integrated circuit die 200’ are shown dash lines in FIGS. 2A, 2B, and 2C for illustrative purposes. The carrier 112 may be a semiconductor carrier, a glass carrier, a ceramic carrier, or the like. The carrier 112 may be a wafer. In some embodiments, the adhesive 114 is a thermal-release layer, such as an epoxy-based light-to-heat-conversion (LTHC) release material, which loses its adhesive property when heated. In some embodiments, the adhesive 114 is a UV glue, which loses its adhesive property when exposed to UV light.

The projected lower integrated circuit die 200’ may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE die), the like, or combinations thereof. The materials and manufacturing processes of the features in the projected lower integrated circuit dies 200’ may be found by referring to the like features in the upper integrated circuit die 100. The projected lower integrated circuit die 200’ may include a semiconductor substrate 202, which may have an active surface (e.g., the surface facing upwards in FIG. 2A), which may be called a front side, and an inactive surface (e.g., the surface facing downwards in FIG. 2A), which may be called a back side. The back side of the semiconductor substrate 202 may also be referred to as a back side of the projected lower integrated circuit die 200’ and the front side of the semiconductor substrate 202 may face a front side of the projected lower integrated circuit die 200’.

Devices (not separately illustrated) may be disposed at the active surface of the semiconductor substrate 202. The devices may be active devices (e.g., transistors, diodes, etc.), capacitors, resistors, or the like. The devices may generate a large amount of heat during operation. An interconnect structure 204 may be disposed on the active surface of the semiconductor substrate 202. The interconnect structure 204 may interconnect the devices to form an integrated circuit of projected lower integrated circuit die 200’. The interconnect structure 204 may comprise metallization patterns 203 in dielectric layers 206. The metallization patterns 203 may be electrically coupled to the devices. The interconnect structure 204 may further comprise a seal ring 205 in the dielectric layers 206. The seal ring 205 is shown in dash lines in FIG. 2C for illustrative purposes. In some embodiments, the seal ring 205 extend through the dielectric layers 206. The seal ring 205 may encircle the metallization patterns 203 in the top-down view and a region between the seal ring 205 and sidewalls of the interconnect structure 204 may be referred to as a KOZ of the interconnect structure 204. The KOZ may be free of the metallization patterns 203. The seal ring 205 may be formed of the same or similar material and by the same or similar process as the metallization patterns 203. The seal ring 205 may be electrically isolated from the integrated circuit of the projected lower integrated circuit die 200’. Conductive vias 207 may be disposed in the semiconductor substrate 202. The conductive vias 207 may be electrically coupled to the metallization patterns 203 of the interconnect structure 204. The semiconductor substrate 202 may be thinned in a subsequent process to expose the conductive vias 207 at the inactive surface of the semiconductor substrate 202. After the thinning process, the conductive vias 207 may be referred to as through-substrate vias (TSV).

A bonding layer 208 may be disposed on the interconnect structure 204 at the front side of the projected lower integrated circuit die 200’. The bonding layer 208 may be formed of the same or similar material and by the same or similar process as the bonding layer 108. One or more passivation layer(s) (not separately illustrated) may be disposed between the bonding layer 208 and the interconnect structure 204. Active die connectors 210 and dummy die connectors 211 may be disposed in the bonding layer 208. The active die connectors 210 and dummy die connectors 211 may be also referred to as bonding pads and may be used for bonding with other integrated circuit dies in a subsequent process. The active die connectors 210 may be electrically coupled with the metallization patterns 203 and the integrated circuit of the projected lower integrated circuit die 200’. The dummy die connectors 211 may be electrically isolated from the integrated circuit of the projected lower integrated circuit die 200’. As shown in FIG. 2C, the active die connectors 210 may be encircled by the seal ring 205 in the top-down view, and the dummy die connectors 211 may be outside the seal ring 205 in the top-down view. Some of the dummy die connectors 211 may be adjacent corners of the projected lower integrated circuit die 200’ in the top-down view. The dummy die connectors 211 may be directly over and adjacent the KOZ 0f interconnect structure 204. The dummy die connectors 211 may subsequently bond with the corresponding dummy die connectors 111 of the upper integrated circuit dies 100, which may enhance the bonding strength between the upper integrated circuit dies 100 and the projected lower integrated circuit die 200’ in regions adjacent the KOZs of the upper integrated circuit dies 100 and the projected lower integrated circuit die 200’, as described in great details below.

The active die connectors 210 and the dummy die connectors 211 may have shapes of circles, polygons (e.g., rectangles), or the like in the top-down view. The dummy die connectors 211 may have larger sizes than the active die connectors 210 in the top-down view. In the embodiments shown in FIGS. 2A, 2B, and 2C, the active die connectors 210 and the dummy die connectors 211 have shapes of circles. The active die connectors 210 may have a diameter D4 in a range from about 5 µm to about 10 µm. The dummy die connectors 211 may have a diameter D5 in a range from about 20 µm to about 60 µm. In some embodiments, the diameter D5 is larger than the diameter D4. The active die connectors 210 and the dummy die connectors 211 may partially or completely extend through the bonding layer 208. In the embodiments shown in FIGS. 2A, 2B, and 2C, the active die connectors 210 and the dummy die connectors 211 completely extend through the bonding layer 208. The active die connectors 210 may have a thickness T4 in a range from about 0.2 µm to about 1 µm. The dummy die connectors 111 may have a thickness T5 in a range from about 0.2 µm to about 1 µm. In some embodiments, the thickness T4 equals to the thickness T5.

The active die connectors 210 and the dummy die connectors 211 may be formed by one or more damascene processes, such as single damascene processes, dual damascene processes, or the like. In some embodiments, the active die connectors 210 and the dummy die connectors 211 are formed of the same material as the active die connectors 110 and the dummy die connectors 111, such as copper. In such embodiments, the active die connectors 210 and the dummy die connectors 211 may be formed by a same process. In some embodiments, the active die connectors 210 and the dummy die connectors 211 are formed of different materials. For example, the active die connectors 210 may be formed of copper and the dummy die connectors 211 may be formed of aluminum, solder, or the like. In such embodiments, the active die connectors 210 and the dummy die connectors 211 may be formed by different processes. In some embodiments, the dummy die connectors 111 and the dummy die connectors 211 are formed of the same material. In some embodiments, the dummy die connectors 111 and the dummy die connectors 211 are formed of different materials. For example, the dummy die connectors 111 may be formed of copper or aluminum and the dummy die connectors 211 may be formed of solder, or the dummy die connectors 111 may be formed of solder and the dummy die connectors 211 may be formed of copper or aluminum.

FIG. 2D shows a region 209 of the structure shown in FIG. 2B, in accordance with some embodiments. The active die connectors 210 may comprise a barrier sublayer 210A and a conductive sublayer 210B, and the dummy die connectors 211 may comprise a barrier sublayer 211A and a conductive sublayer 211B. The conductive sublayer 210B and the conductive sublayer 211B may comprise the same or similar materials as described above with respect to the conductive sublayer 110B and the conductive sublayer 111B, respectively. The barrier sublayer 210A and the barrier sublayer 211A may prevent the materials of the conductive sublayer 210B and the conductive sublayer 211B from diffusing into the interconnect structure 204. The barrier sublayer 210A and the barrier sublayer 211A may be formed of the same or similar materials and by the same or similar process as described above with respect to the barrier sublayer 110A and the barrier sublayer 111A, respectively. The barrier sublayer 210A and the barrier sublayer 211A may have a thickness T6 in a range from about 0.05 µm to about 0.3 µm.

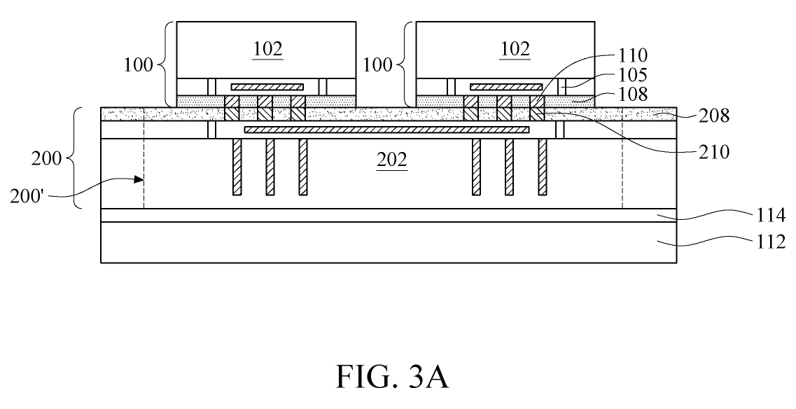

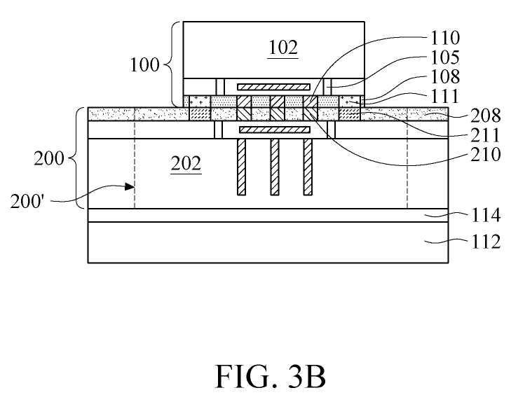

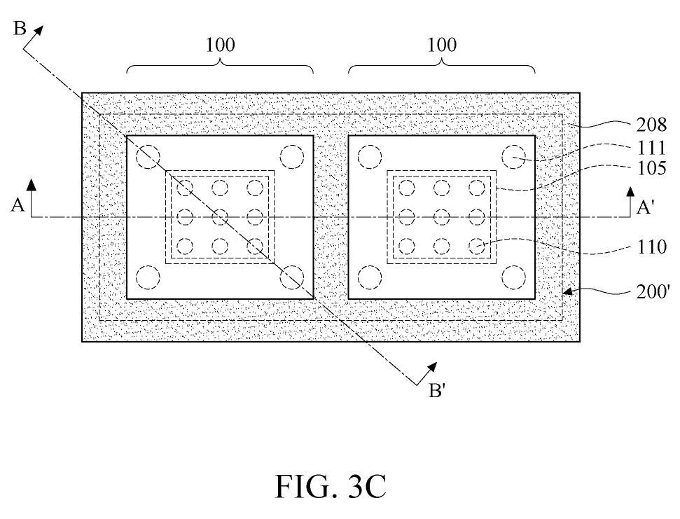

In FIGS. 3A, 3B, and 3C, the upper integrated circuit dies 100 are bonded to the wafer structure 200. The cross-sectional view shown in FIG. 3A may be obtained along reference cross-section A-A’ in the top-down view shown in FIG. 3C and cross-sectional view shown in FIG. 3B may be obtained along reference cross-section B-B’ in the top-down view shown in FIG. 3C. The active die connectors 110, the dummy die connectors 111, and the seal ring 105 are shown in dash lines in FIG. 3C for illustrative purposes. The wafer structure 200 may be subsequently singulated into to one or more lower integrated circuit dies 200’. Sidewalls (e.g., borders) of the projected lower integrated circuit die 200’ are shown dash lines in FIGS. 3A, 3B, and 3C for illustrative purposes. FIGS. 3A, 3B, and 3C show a layout of two the upper integrated circuit dies 100 on the projected lower integrated circuit die 200’ as an example. Other numbers (e.g., three, four) of the upper integrated circuit dies 100 with other layouts on the projected lower integrated circuit die 200’ are contemplated.

The upper integrated circuit dies 100 may be bonded to the projected lower integrated circuit die 200’ in the wafer structure 200 by bonding the bonding layers 108 of the upper integrated circuit dies 100 to the bonding layer 208 of the projected lower integrated circuit die 200’ as well as bonding the die connectors (e.g. the active die connectors 110 and the dummy die connectors 111) of the upper integrated circuit dies 100 to the corresponding die connectors (e.g. the active die connectors 210 and the dummy die connectors 211) of the projected lower integrated circuit die 200’, respectively. The bonding between the bonding layers 108 and the bonding layer 208 may be direct dielectric-to-dielectric bonding. The bonding between the active die connectors 110 and the active die connectors 210 as well as the bonding between the dummy die connectors 111 and the dummy die connectors 211 may be direct metal-to-metal bonding.

The bonding process may include a surface treatment step, a pressing step, and an annealing step. During the surface treatment step, surfaces of the bonding layers 108, the active die connectors 110, and the dummy die connectors 111 of the upper integrated circuit dies 100 as well as surfaces of the bonding layers 208, the active die connectors 210, and the dummy die connectors 211 of the wafer structure 200 may be cleaned and treated with plasma or the like. Then, the upper integrated circuit dies 100 may be placed on the projected lower integrated circuit die 200’ in the wafer structure 200. A small pressing force may be applied to press the upper integrated circuit dies 100 against the wafer structure 200 during the press step at a low temperature, such as room temperature. After the pressing step, dielectric-to-dielectric bonds may be formed between the bonding layers 108 and the bonding layer 208.

The bonding strength between the bonding layers 108 and the bonding layer 208 may be improved in the subsequent annealing step at a higher temperature. Further, during the annealing step, the material of the active die connectors 110 may intermingle and bond with the material of the active die connectors 210 and the material of the dummy die connectors 111 may intermingle and bond with the material of the dummy die connectors 211, so that metal-to-metal bonds may be formed. The bonding between the dummy die connectors 111 and the dummy die connectors 211 may enhance the bonding strength between the upper integrated circuit dies 100 and the projected lower integrated circuit die 200’ in regions adjacent KOZs of the upper integrated circuit dies 100 and the projected lower integrated circuit die 200’, thereby eliminating or reducing the risk of delamination of the upper integrated circuit dies 100 during the manufacturing and the operation of the integrated circuit package. As a result, the performance and reliability of the integrated circuit package may be improved.

In the embodiments illustrated in FIGS. 3A, 3b, and 3C, the sizes and shapes of the active die connectors 110 are the same or similar to those of the corresponding active die connectors 210, and the sizes and shapes of the dummy die connectors 111 are the same or similar to those of the corresponding dummy die connectors 211. In other embodiments, the sizes and shapes of the active die connectors 110 are the different from those of the corresponding active die connectors 210, and/or the sizes and shapes of the dummy die connectors 111 are different from those of the corresponding dummy die connectors 211.

In the embodiments illustrated in FIGS. 3A, 3b, and 3C, the active die connectors 110 are completely aligned with the corresponding active die connectors 210, and the dummy die connectors 111 are completely aligned with the corresponding dummy die connectors 211. In other embodiments, the active die connectors 110 are partially aligned with the corresponding active die connectors 210 with a misalignment smaller than about 3 µm, and/or the dummy die connectors 111 are partially aligned with the corresponding dummy die connectors 211 with a misalignment smaller than about 3 µm.

The above description with respect to FIGS. 3A, 3b, and 3C uses a front-to-front bonding configuration in accordance with some embodiments, wherein the front sides of the upper integrated circuit dies 100 may face the front side of the projected lower integrated circuit die 200’ after bonding. In other embodiments, other bonding configurations may be used, such as a front-to-back bonding configuration, wherein the front sides of upper integrated circuit dies 100 may face the back side of the projected lower integrated circuit die 200’ or the back sides of upper integrated circuit dies 100 may face the front side of the projected lower integrated circuit die 200’.

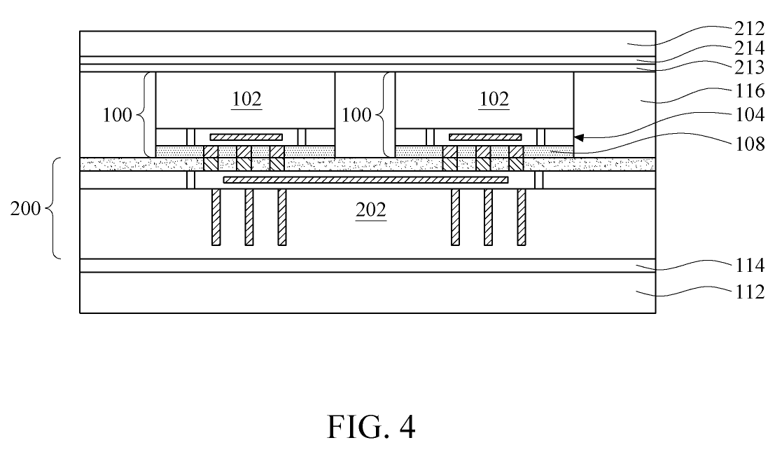

In FIG. 4, a gap-fill layer 116 is formed around the upper integrated circuit dies 100 and a carrier 212 is bonded to surfaces of the semiconductor substrates 102 and the gap-fill layer 116. The gap-fill layer 116 may encircle the upper integrated circuit dies 100 in the top-down view. The gap-fill layer 116 may extend along sidewalls of the upper integrated circuit dies 100 (e.g., the semiconductor substrates 102, the interconnect structure 104, and the bonding layer 108). The gap-fill layer 116 may be an insulating layer and may be formed of a dielectric material, such as silicon oxide, PSG, BSG, BPSG, a TEOS based oxide, or the like, which may be formed by a suitable deposition process such as CVD, ALD, or the like. Initially, the gap-fill layer 116 may cover the surfaces the semiconductor substrates 102. A thinning process may be performed to level the surfaces of the gap-fill layer 116 the surfaces the semiconductor substrates 102. The thinning process may be a chemical-mechanical polishing (CMP) process, a grinding process, an etch-back process, combinations thereof, or the like. After the thinning process, the surfaces of the semiconductor substrates 102 and the gap-fill layer 116 may be substantially coplanar (within process variations).

The carrier 212 may be a semiconductor carrier, a glass carrier, a ceramic carrier, or the like. The carrier 212 may be a wafer having the same or similar size as the carrier 112. In some embodiments, the carrier 212 is bonded to the semiconductor substrates 102 and the gap-fill layer 116 using bonding layers 213 and 214. The bonding layer 213 may be formed on the semiconductor substrates 102 and the gap-fill layer 116, and the bonding layer 214 may be formed on the carrier 212. The bonding layer 213 and the bonding layer 214 may each comprise a dielectric material, such as silicon dioxide or the like, and may be formed by a suitable deposition process such as CVD, ALD, or the like. The structure over the carrier 112 may be bonded to the carrier 212 by bonding the bonding layer 213 and the bonding layer 214 by the same or similar process used for bonding the bonding layer 108 and the bonding layer 208 described with respect to FIGS. 3A, 3b, and 3C.

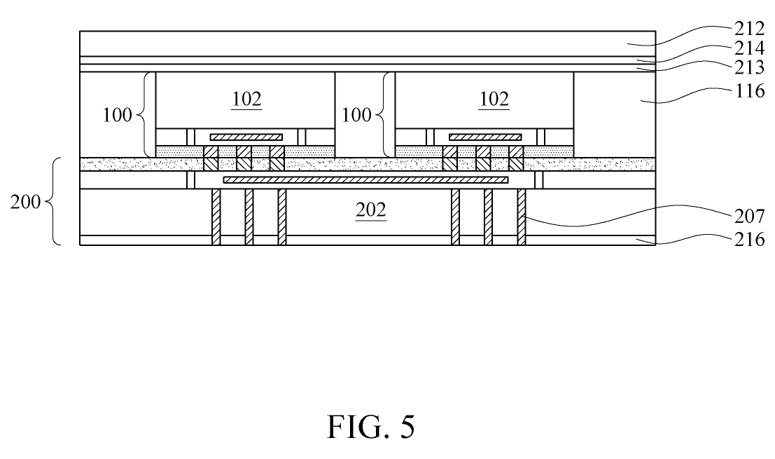

In FIG. 5, the carrier 112 and the adhesive 114 are removed, the semiconductor substrate 202 of the wafer structure 200 is thinned to expose the conductive vias 207, and a dielectric layer 216 is formed on the inactive surface of the semiconductor substrate 202. The removal process of the carrier 112 and the adhesive 114 may include projecting a light beam such as a laser beam or a UV light beam on the adhesive 114 so that the adhesive 114 decomposes upon exposure to the light beam. Then the carrier 112 may be removed. The thinning process of the semiconductor substrate 202 may be a CMP process, a grinding process, an etch-back process, combinations thereof, or the like. After the thinning process portions of the conductive vias 207 may protrude from the inactive surface of the semiconductor substrate 202.

Then the dielectric layer 216 may be deposited to cover the exposed sidewalls of the conductive vias 207. In some embodiments, the dielectric layer 216 comprises polybenzoxazole (PBO), polyimide, a benzocyclobutene (BCB) based polymer, or the like, and is formed by a suitable coating process such as spin coating, lamination, or the like. In some embodiments, the dielectric layer 216 comprises silicon dioxide, silicon nitride, silicon oxynitride, or the like, and is formed by a suitable deposition process such as CVD, ALD, or the like. Initially, the dielectric layer 216 may cover the bottom surfaces the conductive vias 207. Another thinning process may be performed to level the bottom surfaces of the dielectric layer 216 and the conductive vias 207. The thinning process may be a CMP process, a grinding process, an etch-back process, combinations thereof, or the like. After the thinning process, the bottom surfaces of the dielectric layer 216 and the conductive vias 207 may be substantially coplanar (within process variations).

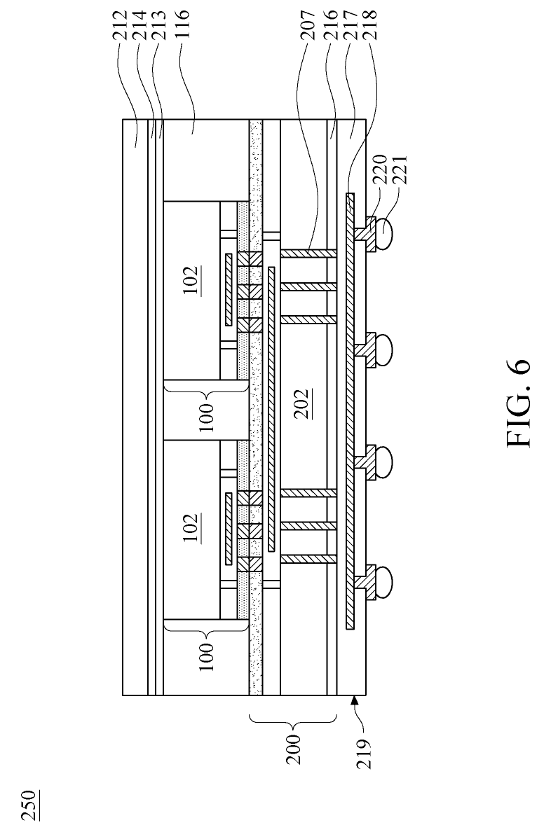

In FIG. 6, a redistribution structure 219 is formed on the bottom surfaces of the dielectric layer 216 and the conductive vias 207, and under-bump metallizations (UBMs) 220 and electrical connectors 221 are formed on the redistribution structure 219. The structure shown in FIG. 6 may be referred to as a wafer structure 250. The redistribution structure 219 may include dielectric layers 217 and metallization patterns 218 in the dielectric layers 217. The dielectric layers 217 may be low-k dielectric layers comprising a suitable dielectric material, such as PBO, polyimide, a BCB-based polymer, silicon dioxide, silicon nitride, silicon oxynitride, or the like. The dielectric layers 217 may be formed by spin coating, lamination, CVD, ALD, or the like. The metallization patterns 218 may include metal lines and vias, which may be formed in the dielectric layers 217 by damascene processes, such as single damascene processes, dual damascene processes, or the like. The metallization patterns 218 may be formed of a suitable conductive material, such as copper, tungsten, aluminum, silver, gold, a combination thereof, or the like. The metallization patterns 218 may be electrically coupled to the conductive vias 207. The UBMs 220 may have portions extending along a bottom surface of the dielectric layers 217 and portions extending through the dielectric layers 217 to electrically couple to the metallization patterns 218.

As an example, to form the UBMs 220, portions of the dielectric layers 217 (specifically, at least the bottom layer of the dielectric layers 217) may be patterned to form openings exposing portions of the metallization patterns 218. The patterning may be done by an acceptable photolithography process, such as forming a mask then performing an anisotropic etching. The mask may be removed after the patterning. A seed layer may be formed on the dielectric layers 217, in the openings through the dielectric layers 217, and on the exposed portions of the metallization patterns 218. The seed layer may be a metal layer, which may be a single layer or a composite layer comprising a plurality of sub-layers formed of different materials. The seed layer may be formed using a suitable deposition process, such as PVD or the like. A photoresist may be then formed and patterned on the seed layer. The patterning may form openings through the photoresist to expose the seed layer. The pattern of the photoresist may correspond to the shapes, sizes, and locations of the UBMs 220. A conductive material may be formed in the openings of the photoresist and on the exposed portions of the seed layer. The conductive material may be formed by plating, such as electroless plating, electroplating, or the like. The conductive material may comprise a metal or a metal alloy, such as copper, titanium, tungsten, aluminum, the like, or combinations thereof. Then the photoresist and portions of the seed layer on which the conductive material is not formed may be removed. The remaining portions of the seed layer and conductive material may form the UBMs 220.

Electrical connectors 221 may be formed on the UBMs 220. The electrical connectors 221 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 221 comprise a conductive material such as solder, copper, aluminum, gold, nickel, silver, palladium, tin, the like, or a combination thereof. The electrical connectors 221 may be formed by initially forming a layer of solder through evaporation, electroplating, printing, solder transfer, ball placement, or the like. Once the layer of solder has been formed on the structure, a reflow may be performed to shape the solder into the desired bump shapes. In some embodiments, the electrical connectors 221 comprise metal pillars, such as a copper pillar, formed by a sputtering, printing, electroplating, electroless plating, CVD, or the like, which are solder free and have substantially vertical sidewalls. A metal cap layer may be formed on top of the metal pillars by a plating process.

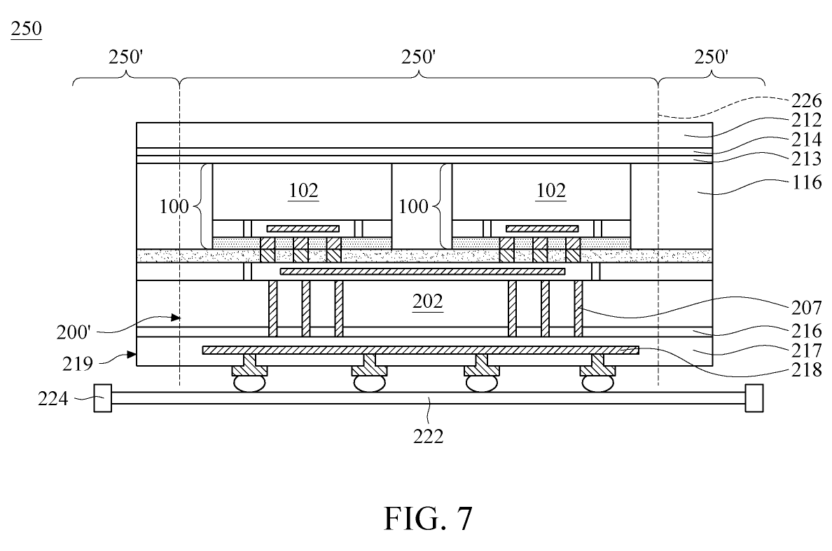

In FIG. 7, the wafer structure 250 is singulated into individual integrated circuit package components 250’. As the same time, wafer structure 200 is singulated into individual lower integrated circuit die 200’. The processes discussed above may be performed using wafer-level processing. The carrier 212 may be a wafer and may include many structures (not separately illustrated) similar to the one illustrated in FIG. 7. The wafer structure 250 may be placed on a tape 222 supported by a frame 224. The wafer structure 250 may be then singulated along scribe lines 226, so that the wafer structure 250 may be separated into individual integrated circuit package components 250’. The singulation process may include a sawing process, a laser cutting process, or the like. A cleaning process or rinsing process may be performed after the singulation process.

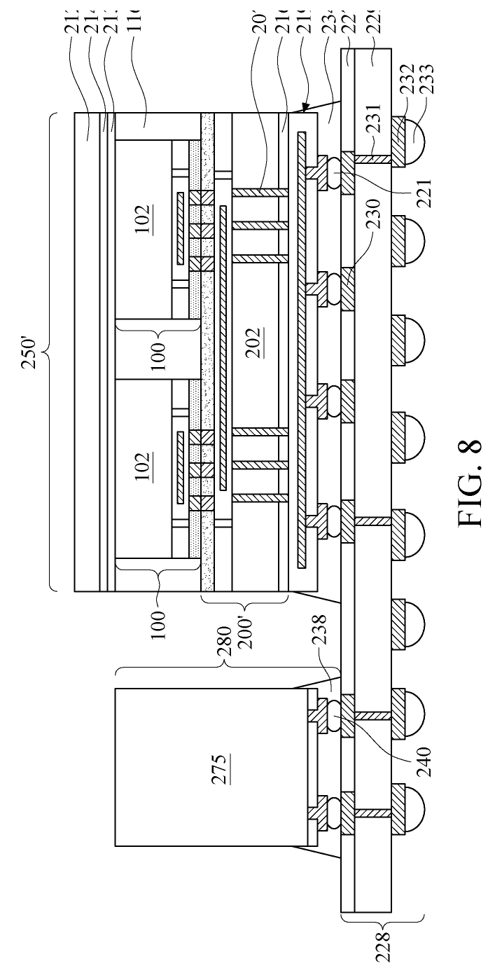

In FIG. 8, the integrated circuit package component 250’ is bonded to an integrated circuit package component 228 and an underfill 234 is formed between the integrated circuit package component 250’ and the integrated circuit package component 228. Further, an integrated circuit package component 280 is bonded to the integrated circuit package component 228 beside the integrated circuit package component 250’ and an underfill 238 is formed between the integrated circuit package component 280 and the integrated circuit package component 228.

The semiconductor package component 228 may comprise a substrate 229, dielectric layers 227 on a first side of the substrate 229, conductive features 230 in the dielectric layers 227, and conductive features 232 on a second side of the substrate 229. The conductive features 230 may comprise conductive lines and conductive vias. The conductive features 232 may comprise UBMs. Conductive vias 231 may extend through the substrate 229 and may electrically couple the conductive features 230 to the conductive features 232. Electrical connectors 233 may be on the conductive features 232 and may be used to bond to an external device, such as package substrate, printed circuit board (PCB), or the like. The semiconductor package component 228 may be referred to as an interposer.

During the bonding process between the integrated circuit package component 250’ and the integrated circuit package component 228, the electrical connectors 221 may be reflowed to bond the integrated circuit package component 250’ to exposed portions of the conductive features 230. The electrical connectors 221 may electrically couple the integrated circuit package component 228 to the integrated circuit package component 250’. The underfill 234 may surround the electrical connectors 221 and protect the joints resulting from the reflowing of the electrical connectors 221. The underfill 234 may encircle the integrated circuit package component 250’ in the top-down view. The underfill 234 may be formed by a capillary flow process after the integrated circuit package component 250’ is attached or by a suitable deposition method before the integrated circuit package component 250’ is bonded. The underfill 234 may be subsequently cured.

The integrated circuit package component 280 may comprise one or more integrated circuit dies in an active region 275 of the integrated circuit package component 280. In some embodiments, the active region 275 comprises a stack of interconnected memory dies and the integrated circuit package component 280 is referred to as a high bandwidth memory (HBM) device. The electrical connectors 240 of the integrated circuit package component 280 may electrically couple the integrated circuit package component 228 to the integrated circuit package component 280. The electrical connectors 240 may be formed of the same or similar material and by the same or similar process as the electrical connectors 221. The underfill 238 may surround the electrical connectors 240 and may encircle the integrated circuit package component 280 in the top-down view. The underfill 238 may be formed of the same or similar material and by the same or similar process as the underfill 234.

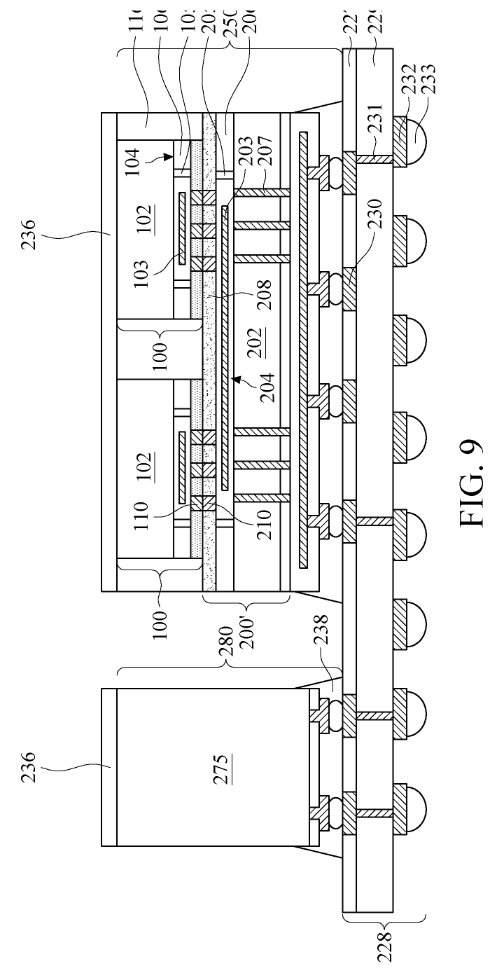

In FIG. 9, the carrier 212, the bonding layer 213, and the bonding layer 214 are removed from the integrated circuit package component 250’, and adhesive layer 236 is formed on the gap-fill layer 116 and the upper integrated circuit dies 100 of the integrated circuit package component 250’ as well as the active region 275 of the integrated circuit package component 280. The carrier 212, the bonding layer 213, and the bonding layer 214 may be removed by a CMP process, a grinding process, an etch-back process, combinations thereof, or the like. The adhesive layer 236 may comprise a thermal interface material (TIM), which may be a material with high thermal conductivity, such as, thermal paste, gel-based thermal adhesive, graphite, graphene film, the like, or the combinations thereof.

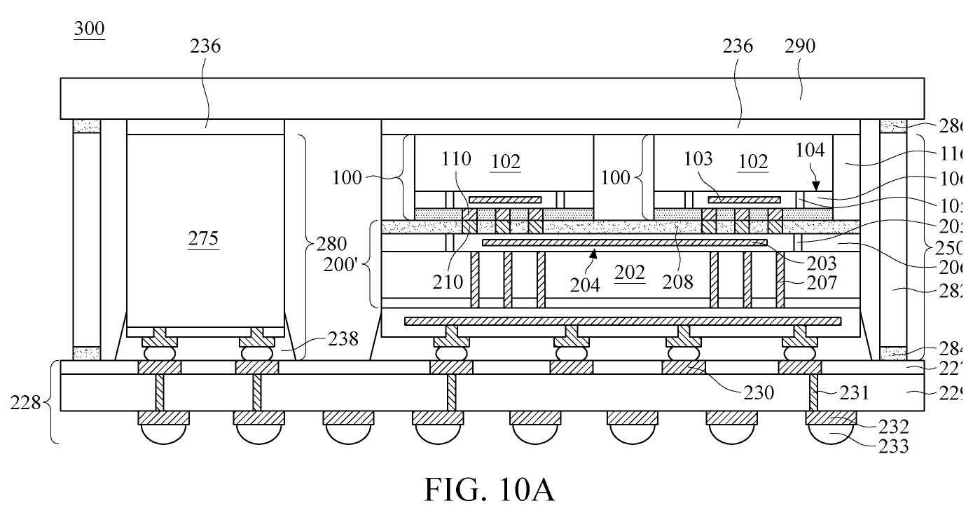

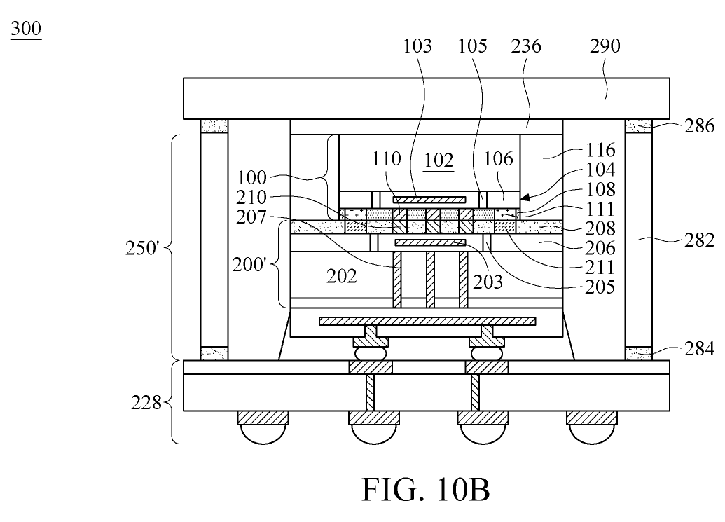

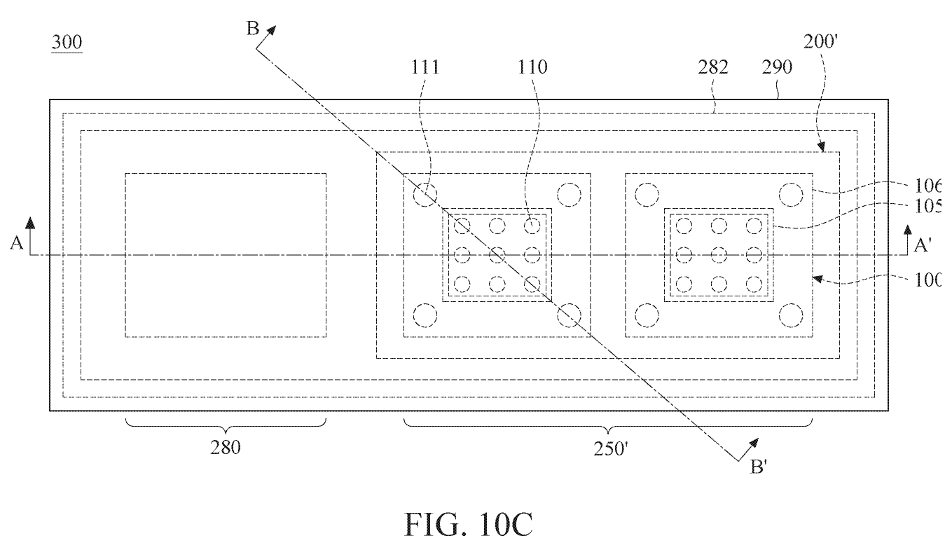

In FIGS. 10A, 10B, and 10C, a stiffener ring 282 is attached to the integrated circuit package component 228 and a lid 290 is attached to the stiffener ring 282 as well as the integrated circuit package component 250’ and the integrated circuit package component 280. The structure shown in FIGS. 10A, 10B, and 10C may be referred to as an integrated circuit package 300. The cross-sectional view shown in FIG. 10A may be obtained along reference cross-section A-A’ in the top-down view shown in FIG. 10C and cross-sectional view shown in FIG. 10B may be obtained along reference cross-section B-B’ in the top-down view shown in FIG. 10C. The upper integrated circuit dies 100, some features of the upper integrated circuit dies 100, the lower integrated circuit die 200’, the integrated circuit package component 280, and the stiffener ring 282 are shown in dash lines in FIG. 10C for illustrative purposes.

The stiffener ring 282 may be used to provide additional support to the integrated circuit package component 228 during subsequent manufacturing processes to reduce warpage or other types of deformation of the integrated circuit package component 228. The stiffener ring 282 may be formed of a material with a large hardness value, such as a metal, metal alloy, or the like. The stiffener ring 282 may be attached to the integrated circuit package component 228 by an adhesive 284, such as an epoxy, glue, or the like.

The lid 290 may be used to dissipate heat generated by the integrated circuit package component 250’ and the integrated circuit package component 280 during operation of the integrated circuit package 300. The lid 290 may be attached to the integrated circuit package component 250’ and the integrated circuit package component 280 by the adhesive layers 236, and to the stiffener ring 282 by an adhesive 286, such as an epoxy, glue, or the like. The lid 290 may be formed of a metal or a metal alloy, such as copper, stainless steel, or the like. Due to the bonding between the dummy die connectors 111 of the upper integrated circuit dies 100 and the dummy die connectors 211 of the lower integrated circuit die 200’, the risk of delamination of the upper integrated circuit dies 100 may be eliminated or reduced, which may lead to the heat generated in the lower integrated circuit die 200’ being more effectively transferred to the lid 290 and dissipated. As a result, the performance and reliability of the integrated circuit package 300 may be improved.

The embodiments may have some advantageous features. By bonding the dummy die connectors 111 and the dummy die connectors 211, the bonding strength between the upper integrated circuit dies 100 and the lower integrated circuit die 200’ in the regions adjacent KOZs of the upper integrated circuit dies 100 and the lower integrated circuit die 200’ may be enhanced, which may eliminate or reduce the risk of delamination of the upper integrated circuit dies 100 during the manufacturing and the operation of the integrated circuit package 300. As a result, the heat generated in the lower integrated circuit die 200’ may be more effectively dissipated, thereby improving the performance and reliability of the integrated circuit package 300.

In an embodiment, an integrated circuit package includes a first die, including: a first semiconductor substrate; a first interconnect structure on the first semiconductor substrate, the first interconnect structure including: a first plurality of dielectric layers; a first plurality of metallization patterns in the first plurality of dielectric layers; and a first seal ring in the first plurality of dielectric layers, wherein the first seal ring encircles the first plurality of metallization patterns in a top-down view; a first bonding layer on the first interconnect structure; a first die connector in the first bonding layer, wherein the first seal ring encircles the first die connector in the top-down view; and a second die connector in the first bonding layer, wherein the second die connector is outside the first seal ring in the top-down view. In an embodiment, the first die connector is electrically coupled to an integrated circuit of the first die. In an embodiment, the second die connector is electrically isolated from an integrated circuit of the first die. In an embodiment, the second die connector has a larger size than the first die connector in the top-down view. In an embodiment, the first die connector and the second die connector include a same first material, and wherein the first material is copper. In an embodiment, the first die connector includes a first material and the second die connector includes a second material, wherein the first material is copper and the second material is solder. In an embodiment, the integrated circuit package further includes a second die, wherein the second die includes a second interconnect structure having a second seal ring, a second bonding layer on the second interconnect structure bonded to the first bonding layer, a third die connector in the second bonding layer bonded to the first die connector, and a fourth die connector in the second bonding layer bonded to the second die connector. In an embodiment, the second seal ring encircles the third die connector in the top-down view, and wherein the fourth die connector is outside the second seal ring in the top-down view.

In an embodiment, an integrated circuit package includes a first die, including: a first semiconductor substrate; a first interconnect structure on the first semiconductor substrate, wherein the first interconnect structure includes a first seal ring; a first bonding layer on first interconnect structure; a first die connector in the first bonding layer, wherein the first die connector is electrically coupled to an integrated circuit of the first die; and a second die connector in the first bonding layer, wherein the second die connector is electrically isolated from the integrated circuit of the first die, and wherein the first seal ring is disposed between the first die connector and the second die connector in a top-down view. In an embodiment, the first die connector is encircled by the first seal ring in the top-down view. In an embodiment, the second die connector is directly over a keep-out zone (KOZ) of the first interconnect structure. In an embodiment, the second die connector has a larger diameter than the first die connector in the top-down view. In an embodiment, the first die connector includes a first material, and wherein the second die connector includes a second material different from the first material. In an embodiment, the first material is copper and the second material is aluminum or solder.

In an embodiment, a method of forming an integrated circuit includes attaching a first die to a carrier, the first die including: a first semiconductor substrate; a first interconnect structure on the first semiconductor substrate, wherein the first interconnect structure includes a first seal ring; a first bonding layer on the first interconnect structure; and a first die connector and a second die connector in the first bonding layer, wherein the first seal ring encircles the first die connector in a top-down view, and wherein the second die connector is outside the first seal ring in the top-down view; and bonding a second die to the first bonding layer, the first die connector, and the second die connector. In an embodiment, the first die connector is electrically coupled to an integrated circuit of the first die, and wherein the second die connector is electrically isolated from the integrated circuit of the first die. In an embodiment, the second die includes a second interconnect structure having a second seal ring, a second bonding layer on the second interconnect structure, and a third die connector and a fourth die connector in the second bonding layer, wherein the second bonding layer is bonded to the first bonding layer by dielectric-to-dielectric bonding, and wherein the third die connector and the fourth die connector are bonded to the first die connector and the second die connector, respectively, by metal-to-metal bonding. In an embodiment, the second seal ring encircles the third die connector in a bottom-up view, and wherein the fourth die connector is outside the second seal ring in the bottom-up view. In an embodiment, the second die connector is adjacent a corner of the first die in the top-down view and wherein the fourth die connector is adjacent a corner of the second die in a bottom-up view. In an embodiment, the first die connector and the third die connector are formed of a first material, wherein the second die connector and the fourth die connector are formed of a second material, and wherein the first material is different from the second material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package, comprising:
an upper integrated circuit die, comprising:
a first semiconductor substrate;
a first interconnect structure on the first semiconductor substrate, the first interconnect structure comprising a first seal ring in a first plurality of dielectric layers, wherein a region between the first seal ring and sidewalls of the first interconnect structure is a first keep-out zone;
a first bonding layer on the first interconnect structure;
a first active die connector in the first bonding layer, wherein the first seal ring encircles the first active die connector in a bottom-up view; and
a first dummy die connector in the first bonding layer, wherein the first dummy die connector is outside the first seal ring, directly over the first keep-out zone, and adjacent a corner of the upper integrated circuit die in the bottom-up view, and wherein the first dummy die connector has a larger lateral dimension than the first active die connector; and
a lower integrated circuit die bonded to the upper integrated circuit die, the lower integrated circuit die comprising:
a second semiconductor substrate;
a second interconnect structure on the second semiconductor substrate, the second interconnect structure comprising a second seal ring in a second plurality of dielectric layers, wherein a region between the second seal ring and sidewalls of the second interconnect structure is a second keep-out zone;
a second bonding layer on the second interconnect structure and bonded to the first bonding layer;
a second active die connector in the second bonding layer and bonded to the first active die connector, wherein the second seal ring encircles the second active die connector in a top-down view; and
a second dummy die connector in the second bonding layer and bonded to the first dummy die connector, wherein the second dummy die connector is outside the second seal ring, directly over the second keep-out zone, and adjacent a corner of the lower integrated circuit die in the top-down view, and wherein the second dummy die connector has a larger lateral dimension than the second active die connector.

2. The integrated circuit package of claim 1 wherein the first active die connector is electrically coupled to an integrated circuit of the upper integrated circuit die, the first dummy die connector is electrically isolated from the integrated circuit of the upper integrated circuit die, the second active die connector is electrically coupled to an integrated circuit of the lower integrated circuit die, and the second dummy die connector is electrically isolated from the integrated circuit of the lower integrated circuit die.

3. The integrated circuit package of claim 1 wherein the first bonding layer is bonded to the second bonding layer by dielectric-to-dielectric bonding, and wherein the first active die connector and the first dummy die connector are bonded to the second active die connector and the second dummy die connector, respectively, by metal-to-metal bonding.

4. The integrated circuit package of claim 1, wherein a front side of the upper integrated circuit die faces a front side of the lower integrated circuit die.

5. The integrated circuit package of claim 1, wherein the first active die connector and the first dummy die connector comprise a same material.

6. The integrated circuit package of claim 1, wherein the first active die connector comprises a first material, wherein the first dummy die connector comprises a second material, and wherein the second material is different from the first material.

7. The integrated circuit package of claim 1, wherein the lower integrated circuit die further comprises a conductive via in the second semiconductor substrate, the conductive via electrically coupled to a metallization pattern of the second interconnect structure.

8. The integrated circuit package of claim 1, wherein the first dummy die connector comprises a first barrier sublayer lining a first conductive sublayer, and wherein the second dummy die connector comprises a second barrier sublayer lining a second conductive sublayer.

9. The integrated circuit package of claim 1, wherein the first keep-out zone and the second keep-out zone are free of metallization patterns.

10. A method, comprising:
attaching a wafer structure to a first carrier, the wafer structure comprising:
a first semiconductor substrate;
a conductive via in the first semiconductor substrate;
a first interconnect structure on the first semiconductor substrate, the first interconnect structure comprising a first seal ring;
a first bonding layer on the first interconnect structure;
a first active die connector in the first bonding layer, wherein the first seal ring encircles the first active die connector in a top-down view; and
a first dummy die connector in the first bonding layer, wherein the first dummy die connector is outside the first seal ring in the top-down view;
bonding an upper integrated circuit die to the wafer structure, wherein bonding the upper integrated circuit die to the wafer structure comprises:
bonding a second bonding layer of the upper integrated circuit die to the first bonding layer by dielectric-to-dielectric bonding;
bonding a second active die connector of the upper integrated circuit die to the first active die connector by metal-to-metal bonding; and
bonding a second dummy die connector of the upper integrated circuit die to the first dummy die connector by metal-to-metal bonding;
forming a gap-fill layer around the upper integrated circuit die;
bonding a second carrier to a semiconductor substrate of the upper integrated circuit die and to the gap-fill layer;
removing the first carrier;
thinning the first semiconductor substrate to expose the conductive via;
forming a redistribution structure on the first semiconductor substrate, the redistribution structure electrically coupled to the conductive via;
forming an under-bump metallization on the redistribution structure;
forming an electrical connector on the under-bump metallization; and
singulating the wafer structure into an integrated circuit package component.

11. The method of claim 10, wherein bonding the upper integrated circuit die to the wafer structure comprises facing a front side of the upper integrated circuit die to a front side of the wafer structure.

12. The method of claim 10, wherein bonding the upper integrated circuit die to the wafer structure comprises a surface treatment step, a pressing step performed at a first temperature, and an annealing step performed at a second temperature higher than the first temperature.

13. The method of claim 10, wherein forming the gap-fill layer comprises encircling the upper integrated circuit die in a top-down view and extending the gap-fill layer along sidewalls of the semiconductor substrate of the upper integrated circuit die, an interconnect structure of the upper integrated circuit die, and the second bonding layer of the upper integrated circuit die.

14. The method of claim 10, further comprising thinning surfaces of the semiconductor substrate of the upper integrated circuit die and the gap-fill layer such that the surfaces of the semiconductor substrate of the upper integrated circuit die and the gap-fill layer are substantially coplanar.

15. The method of claim 10, wherein singulating the wafer structure comprises sawing or laser cutting the wafer structure along scribe lines.

16. The method of claim 10, further comprising bonding the integrated circuit package component to an interposer through the electrical connector, and forming an underfill around the electrical connector between the integrated circuit package component and the interposer.

17. A semiconductor device, comprising:
a first integrated circuit die, comprising:
a semiconductor substrate;
an interconnect structure on the semiconductor substrate, the interconnect structure comprising a seal ring in a plurality of dielectric layers, wherein a region between the seal ring and sidewalls of the interconnect structure is a keep-out zone;
a bonding layer on the interconnect structure;
an active die connector in the bonding layer, wherein the active die connector comprises a first barrier sublayer lining sidewalls and a bottom of a first conductive sublayer, and wherein the seal ring encircles the active die connector in a bottom-up view; and
a dummy die connector in the bonding layer, wherein the dummy die connector comprises a second barrier sublayer lining sidewalls and a bottom of a second conductive sublayer, wherein the dummy die connector is outside the seal ring, directly over the keep-out zone, and adjacent a corner of the first integrated circuit die in the bottom-up view, wherein the dummy die connector has a larger lateral dimension than the active die connector, and wherein the first conductive sublayer and the second conductive sublayer are formed of different materials.

18. The semiconductor device of claim 17, wherein the active die connector is electrically coupled to a metallization pattern in the interconnect structure, and wherein the dummy die connector is electrically isolated from the metallization pattern.

19. The semiconductor device of claim 17, further comprising a second integrated circuit die bonded to the first integrated circuit die, the second integrated circuit die comprising an additional bonding layer bonded to the bonding layer, an additional active die connector in the additional bonding layer and bonded to the active die connector, and an additional dummy die connector in the additional bonding layer and bonded to the dummy die connector.

20. The semiconductor device of claim 17, wherein the first conductive sublayer comprises copper, and wherein the second conductive sublayer comprises aluminum or solder.
